(19) United States
(12) Patent Application Publication
(10) Pub. No.: US 2018/0279481 A1
(43) Pub. Date: Sep. 27, 2018

(54) Method of Manufacturing Circuit Boards

(71) Applicant: Isola USA Corp., Chandler, AZ (US)

(72) Inventor: Michael Gay, Sherwood, OR (US)

(21) Appl. No.: 15/761,366

(22) PCT Filed: May 18, 2017
(86) PCT No.: PCT/US2017/033342

§ 371 Date: Mar. 19, 2018

Related U.S. Application Data
(60) Provisional application No. 62/337,979, filed on May 18, 2016.

(51) Int. Cl. H05K 3/02; H05K 3/46; H05K 3/38

(52) U.S. Cl. CPC H05K 3/022; H05K 3/4652; H05K 3/389; H05K 3/385; H05K 3/383

(57) ABSTRACT

Methods for manufacturing electrical circuits on laminates from low profile copper layers where one or more of the circuits have known and reproducible signal losses. The method for manufacturing printed circuit boards (40) comprising the steps of: providing a planar sheet (16) including a planar dielectric material layer having a first planar surface and a second planar surface, and first copper foil sheet (10) having a first planar surface and a second planar surface wherein the first copper foil planar surface is associated with the first dielectric material layer planar surface and wherein the first copper foil sheet first surface and second surface each include a bond enhancement layer (12, 14); and forming a circuit pattern (32, 34, 36) in the first planar copper sheet by removing unnecessary portions of the first planar copper sheet while leaving the circuit pattern copper in place to form an inner layer sheet including a circuit pattern wherein a bond enhancement layer is not applied to the circuit pattern after forming the circuit pattern.

### BACKGROUND OF THE INVENTION

### (1) Field of the Invention

This invention concerns methods for manufacturing electrical circuits on laminates from low profile copper layers where one or more of the circuits have a known and reproducible transmission line total signal loss.

### (2) Description of the Art

Printed circuit board (PCB) designers continue to push the limits of materials used in PCBs for high speed digital applications. New PCB's with transmission lines capable of achieving data rates at or beyond 25 Gb/channel require laminators to develop new designs using laminates and prepregs having novel resin systems, spread and flattened glass fabrics and very low profile copper foils to improve dielectric properties. Each of these design features influences the electrical performance of the finished printed circuit board.

Copper foil technology has continued to develop with new and improved surface topography to improve copper/dielectric bond strengths and to reduce skin effects. Surface topography of copper foil is a contributor to signal loss associated with the material used to fabricate a PCB. Signal loss differences of up to 30% have been seen between foils with a roughness of 5-7 μm and a foil with 2-3 μm roughness. This improvement can be leveraged to improve the overall laminate material performance. However, the signal loss improvement is limited to the copper foil surface that is bonded to and in direct contact with the laminate (dielectric material layer).

Inner layer processing of copper clad laminates to fabricate circuit patterns exposes three faces of the copper transmission line that are treated to enhance bonding to the prepreg or bonding sheet between inner layers. The treating process, commonly referred to as an oxide or bond enhancement process, is accomplished through various means in which the copper surface is modified to enhance the mechanical and/or chemical bond of the treated copper surface with an adjacent dielectric material layer. As with any copper surface modification process, the resulting copper topography differs depending on the type of chemistry used, process controls and capability of the fabricator, and equipment used to process the inner layers. Each of these major contributing factors is magnified when comparing variations in the resulting copper surface topography between printed circuit fabricators.

There are four surfaces on a transmission line transmission line. Of these surfaces, the laminate manufacturer has control over the bottom of the trace—the surface bonded to the laminate (around 40-45% of the perimeter of the cross sectional area depending on the copper weight) and only partial control of the top of the transmission line or the process side of the copper foil. The laminator can choose a foil that has the lowest surface profile that will provide acceptable peel strength and then bond the lowest profile surface, typically the drum side, to the laminate. While the laminator has control of the ‘as shipped’ top copper foil topography and may choose a very low profile copper, the PCB fabricator will typically subject the top surface of the copper or the top surface of the transmission line to a bond enhancement process and it is the selected process and the performance of the selected process that determines the ultimate transmission line top surface and side wall profiles and their subsequent effect on signal loss.

PCB fabricators use a variety of bond enhancement processes and process parameters to modify the top and side wall profiles of transmission lines. The difference in surface topography from the bond enhancement process between printed circuit board fabricators is becoming an issue as the allowable circuit loss specifications continue to be reduced. Fabricator to fabricator bond enhancement surface topography variation is viewed as a growing problem and there is a need to align the process capability of the various printed circuit board fabricators to ensure that each could process inner layers through bond enhancement and meet a tight surface topography specification.

### SUMMARY OF THE INVENTION

One aspect of this invention is a method for manufacturing printed circuit boards comprising the steps of: providing a planar sheet including a planar dielectric material layer having a first planar surface and a second planar surface, and first copper foil sheet having a first planar surface and a second planar surface wherein the first copper foil planer surface is associated with the first dielectric material layer planar surface and wherein the first copper foil sheet first surface and second surface each include a bond enhancment layer; and forming a circuit pattern in the first planar copper sheet by removing unnecessary portions of the first planar copper sheet while leaving the circuit pattern copper in place to form an innerlayer sheet including a circuit pattern wherein a bond enhancment layer is not applied to the circuit pattern.

Another aspect of this invention is a method of manufacturing a plurality of printed circuit boards comprising the steps of: manufacturing a plurality printed circuit boards at a first manufacturing location by the further steps of: providing a planar sheet including a dielectric material layer having a first planar surface and a second planar surface, and a first copper foil sheet having a first planar surface and a second planar surface wherein the first copper foil first planar surface is associated with the dielectric material layer first planar surface and wherein the first copper foil sheet first planar surface and second planar surface each include a bond enhancment layer; forming a circuit pattern in the first copper foil sheet by removing unnecessary portions of the first planar copper sheet while leaving the circuit patter copper in place to form an first manufactured innerlayer sheet including the circuit pattern wherein a bond enhancment layer is not applied to the circuit pattern and wherein the circuit pattern includes a transmission line having a total circuit loss; and incorporating the first manufactured innerlayer sheet into a first manufacuted printed circuit board; and then manufactuing a plurality of printed circuit boards at a second manufacturing location by the further steps of: providing a planar sheet including a dielectric material layer having a first planar surface and a second planar surface, and a first copper foil sheet having a first planar surface and a second planar surface wherein the first copper foil sheet first planar surface is associated with the dielectric material layer first planar surface and wherein the first copper foil sheet first surface and second surface each include a bond enhancment layer; and forming a circuit pattern in the first planar copper sheet by removing unnecessary portions of the first planar copper sheet while leaving the circuit pattern copper in place to form an second manufactured innerlayer sheet including a circuit pattern wherein a bond enhancment layer is not applied to the circuit pattern and wherein the circuit pattern includes a transmission line having a total circuit loss; and incorporating the second manufactured innerlayer sheet into a second manufacuted printed circuit board wherein the transmission line of the first manufactured innnerlayer is essentially identical to the transmission line of the second manufactured innerlayer; repeating steps (a) and (b) a plurality of times to form a plurality of first manufactured innerlayers and second manufactured innerlayers wherein wherein the measured total loss of the transmission line of at least 90 percent of the plurality of first manufactured innerlayer and measured total loss of the transmission line of at least 90 percent of the plurality of second manufactured inner layers differ from one another by no more than 10%.

Still another aspect of this invention is a planar sheet comprising a planar dielectric material layer having a first planar surface and a second planar surface, and first copper foil sheet having a first planar surface and a second planar surface wherein the first copper foil planer surface is associated with the first dielectric material layer planar surface and wherein the first copper foil sheet first surface and second surface each include a bond enhancment layer.

In certain aspects the bond enhancement layers have a Rz roughness of from about 0.25 to about 5.0 microns. In other aspects, the surface roughness of the first planar copper foil sheet first planar surface is less than about 1.5 microns. In still other aspects, the surface roughness of the first copper foil sheet second planar surface is less than about 2.5 microns.

### DESCRIPTION OF THE FIGURES

FIG. 1A and FIG. 1B are photographs of copper foil surfaces after pre-cleaning but before surface oxidation;

FIG. 2A and FIG. 2B are photographs of copper foils surfaces that have been pre-cleaned and then subjected to an oxide treatment step;

FIGS. 3A, 3B and 3C are steps in a method of this invention for forming a circuit;

FIG. 4 is a cutaway view of an exemplary printed circuit board including an innerlayer sheet such as is shown in FIG. 3C; and

FIG. 5 is a schematic of a process for manufacturing printed circuit boards at different manufacturing locations where the printed circuit board include the same or essentially the same circuit.

### DESCRIPTION OF THE CURRENT EMBODIMENT

The present invention relates to methods of manufacturing printed circuit boards using planar material sheets such as resin coated copper sheet, copper clad prepregs or copper clad c-staged laminates wherein the planar sheets include a dielectric material sheet or layer and at least one planar copper foil or sheet surface wherein the copper foil or sheet includes a bond enhancement layer on both planar copper surfaces and wherein the copper foil or sheet is imparted with the bond enhancement layer before circuits are formed in the copper foil or sheet. The present invention is further directed to resin coated copper sheets, copper lad prepregs and copper clad laminates having one or two exposed copper foil or sheet surfaces wherein both planar surfaces of each copper foil or sheet are imparted with a bond enhancement layer.

The methods, prepregs and laminates of this invention include copper foil or sheets that are pre-treated with bond enhancement layers. For purposes of this description, the term “foil” refers to a thin planar copper sheet material made by any known method—e.g., roller copper foils and electrodeposited copper foils—that are useful when resin coated, used as prepreg cladding or otherwise used in manufacturing printed circuit boards.

The copper foil sheets may be selected from copper foils having a variety of thickness and preferably copper foils selected from 2 ounce copper foil, 1 ounce copper foil, ½ ounce copper foil and ¼ ounce copper foil. In addition it is preferred that the copper foil is a low profile copper foil or very low profile copper foil. The term very low profile copper foil is defined as a copper foil having an Rz surface roughness of 1.3 micrometers or less and preferably 0.9 micrometers or less. Typically a low profile copper foil sheet has a thicknesses of from 10 to 400 microns, a very low profile copper sheets has a thicknesses of from about 5 microns to about 200 microns and more narrowly, from about 5 to about 35 microns.

The double treated copper foils of this invention are planar and include a first planar surface and a second planar surface wherein both copper foil planar surfaces are pretreated in a manner that forms a thin bond enhancement layer on each planar surface of the copper foil sheet. Pretreatment can be accomplished by any methods known in the art such as by nodulation treatment, HET foil treatment, MLS foil treatment, surface oxide treatment and other similar treating steps. In one aspect the copper foil first and second planar surfaces are imparted with a bond enhancement layer in a single step using the same pretreatment method. Alternatively, the copper foil first planar surface is imparted with a bond enhancement layer by a first treatment method and the second planar surface is imparted with a bond enhancement layer by a second treatment method.

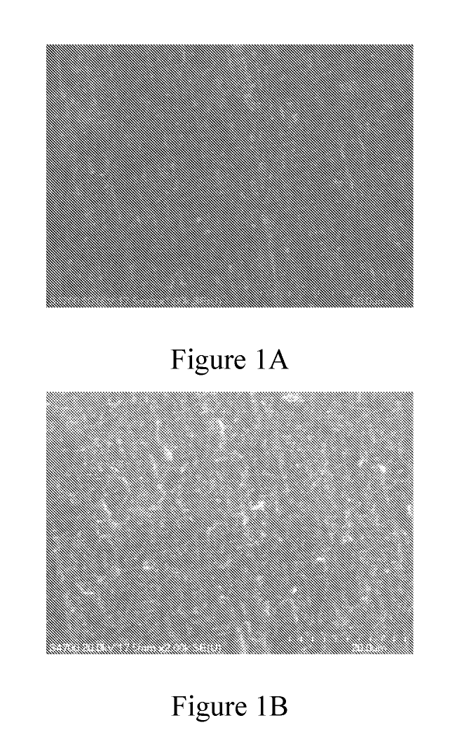

FIG. 1A and FIG. 1B are photographs of the two surfaces of a copper foil sheets before a bond enhancement layer treatment. In general copper foils—before treatment—will have a surface roughness (Rz) that ranges from about 0.4 to about 6.0 μm and preferably about 2.5 μm or less. The term “low profile copper foil” is defined as a copper foil with one planar surface that is bonded to the dielectric layer having an Rz surface roughness of about 2.5 μm or less. For copper foil that is produced by electrodepositing copper or a moving drum, such as is shown in FIGS. 1A and 1B, the drum side of the copper foil will have a surface roughness that is smoother than the non-drum or “matte” side. With such a foil, the matte side may have a surface roughness Rz that is greater than the drum side by as great as 1-3 μm.

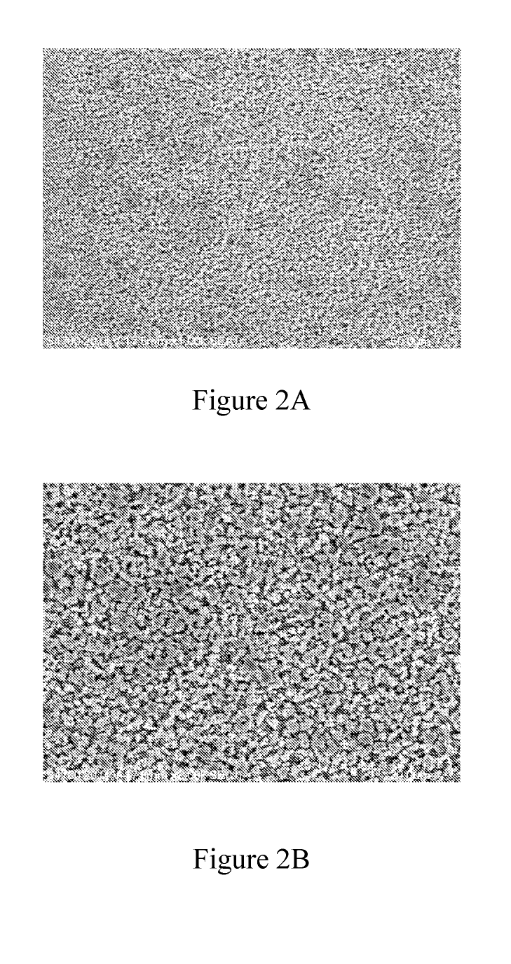

FIG. 2A and FIG. 2B are photographs of the surfaces of a copper foil sheet after pretreatment by one or more bond enhancing methods to form a bond enhancement layer on both copper foil planar surfaces. Bond enhancement methods will typically result in the removal of a thin layer of copper from the copper foil surface—1-2 μm. Additionally bond enhancement methods typically reduce the roughness of the bond enhanced copper foil surfaces in comparison to the pre-bond enhanced surface roughness. In one aspect, the copper foil sheets having bond enhanced surfaces will have Rz surface roughness from about 0.25 to about 5.0 μm, preferably less than about 2.5 μm and most preferably less than about 1.5 μm.

The term “bond enhancement layer” as used herein refers to a surface of the copper foil sheet that is modified in some manner to improve the ability of a copper foil sheet to bond to an adjacent dielectric material layer as evidenced by improved peel strengths and/or to improve the adhesion of a photoresist material to the copper foil surface.

Bond enhancement layers may be formed by any methods known in the art for treating or otherwise modifying the surface of a copper foil sheet in order to improve its adhesion to a dielectric material layer. The methods include chemical method such as applying a silane or other material to the copper foil surface, oxide treatment, chemical cleaning and so forth of the copper foil surface. The methods also include mechanical methods such as micro-etch treatments, pumice treatment.

The bond enhancement layer may further be treated or coated with a material that facilities the adhesion of the copper foil to an adjacent dielectric material layer. For example, the bond enhancement layer may be a silane material layer or the bond enhancement layer may be coated with a silane material layer such as is disclosed, for example, in U.S. Pat. Nos. 5,525,433, 5,622,782, 6,248,401 and 2013/0113523 the specifications of each of which are incorporated herein by reference.

The dielectric material layer or sheets associated with the copper foil layer may be made of any dielectric material that used or that may be used in the printed circuit board art. Examples of dielectric materials include thermosetting resins such as epoxy resin systems and polyimide resin systems. Thermoplastic materials such as polytetrafluorethane may also be employed as dielectric material layers.

The methods and articles of this invention include a planar sheet comprising a dielectric material layer having a first planar surface and an opposing second planar surface that is associated with or adhered to a planar surface of copper foil having, likewise, two planar surfaces where each copper foil planar surface includes a bond enhancement layer.

In one example, the planar sheet is a prepreg. A prepreg is manufactured by the impregnation of fiberglass fabric with specially formulated resins. The resin confers specific electrical, thermal and physical properties to the prepreg. The prepreg is incorporated into a copper clad laminate consisting of an inner layer of prepreg laminated on one or both sides with a thin layer of copper foil having bond enhancement layers on both planar surfaces. The lamination is achieved by pressing together one or more plies of copper and prepreg under intense heat, pressure and vacuum conditions. The bond enhancement layer facilitates the bonding of the copper foil to the prepreg material which is important in order to ensure that the copper foil does not easily peel away from the prepreg material. The prepreg dielectric material is typically b-staged meaning the resin is partially cured.

In another example, the planar sheet may be a fully cured resin or polymer including copper foil layers adhered to one or both of its planar surfaces.

In yet another example, the planar sheet may be a resin coated copper foil sheet. Resin coated copper is useful as a thin dielectric for multilayer high density interconnects. Resin coated copper consists of one or more layers of resin, supported on electrodeposited copper foil. The resin is unsupported. Resin coated copper can serve as an electrical insulating layer while encapsulating the circuitry and also acting as an outer layer conductor. The resin associated with the resin coated copper may be B-staged or C-staged or it may include a combination of a B-staged resin layer and a C-staged resin layer. Resin coated copper can be used with rigid laminate as a cap layer or sequential build up, and also for flex coverlay applications. The elimination of glass reinforcement from resin coated copper allows the mass formation of blind microvias by means other than mechanical drilling.

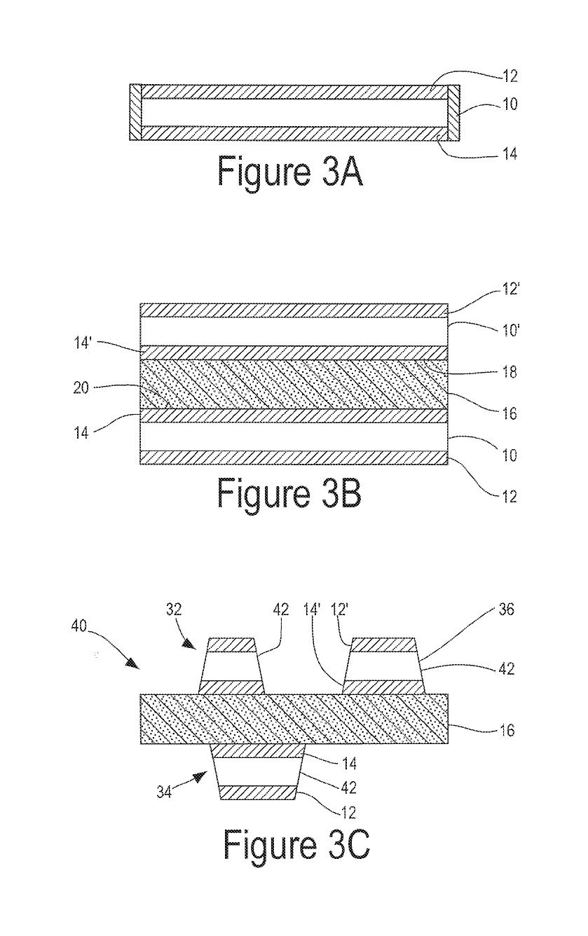

FIGS. 3A, 3B and 3C are representative of certain methods and products of this invention. A double treated (bond enhancement layers on both planar surfaces) copper foil sheet (10) is shown in FIG. 3A. Double treated copper foil sheet (10) further includes a first surface treated planar surface (12) this is a first bond enhancement layer and a second surface treated planar surface (14) that is second bond enhancement layer. In FIG. 3B, two double treated copper foil sheet (10, 10′) are adhered to a planar dielectric material layer (16) such that the first surface treated planar surface (14) of the first copper sheet abuts and is adhered to the first planar surface (18) of planar dielectric material layer (16). In addition, in FIG. 3B, a second optional copper foil sheet (10′) having a first surface treated planar surface (14′) and a second surface treated planar surface (12′) is adhered to the second planar surface (20) of dielectric material layer (16).

In FIG. 3B, the second planar surfaces (12, 12′) remain exposed for further processing. Next, a circuit is formed in double treated foil sheet (10) typically by applying a mask to the first surface treated planar surface and removing the unmasked copper portions by etching. FIG. 3C shows the result of the etching process which is an innerlayer sheet (40) including a plurality of transmission lines (32, 34 and 36) each transmission line including a second bond enhancement layer (12, or 12′), a first bond enhancement layer (14, or 14′) and sidewalls (20) wherein the transmission line sidewalls (42) do not include a bond enhancement layer. In some embodiments, transmission lines may have one or more end walls which also do not include a bond enhancement layer.

The top and bottom of the copper foil or about 80-90% of the perimeter of the cross sectional area of the transmission line surface topography would be the result of a well-controlled copper foil manufacturing process. In other words, when portions of the copper foil is removed to form a circuit, 80-90% of the surface that makes up the circuit—top and bottom—but not the side surfaces—of the circuit are surface treated. As a result, PCB manufactures do not need to apply a bond enhancement layer to the circuit structure after the circuit structure is formed thereby essentially eliminating printed circuit board variations across two or more manufacturing facilities.

Printed circuit board fabricators use copper clad laminates to construct multilayered PCBs in complex processes comprised of multiple operations that are often repeated. In general, the copper surfaces of the laminate are etched to create an electronic circuit. These etched laminates are assembled into a multilayer configuration by inserting one or more plies of insulating prepregs between each etched laminate. Holes (vias) are then drilled and plated in the PCB to establish electrical connections among the layers. The resulting multilayer PCB is an intricate interconnection device on which semiconductors and other components are mounted, which is then incorporated into an end-market product.

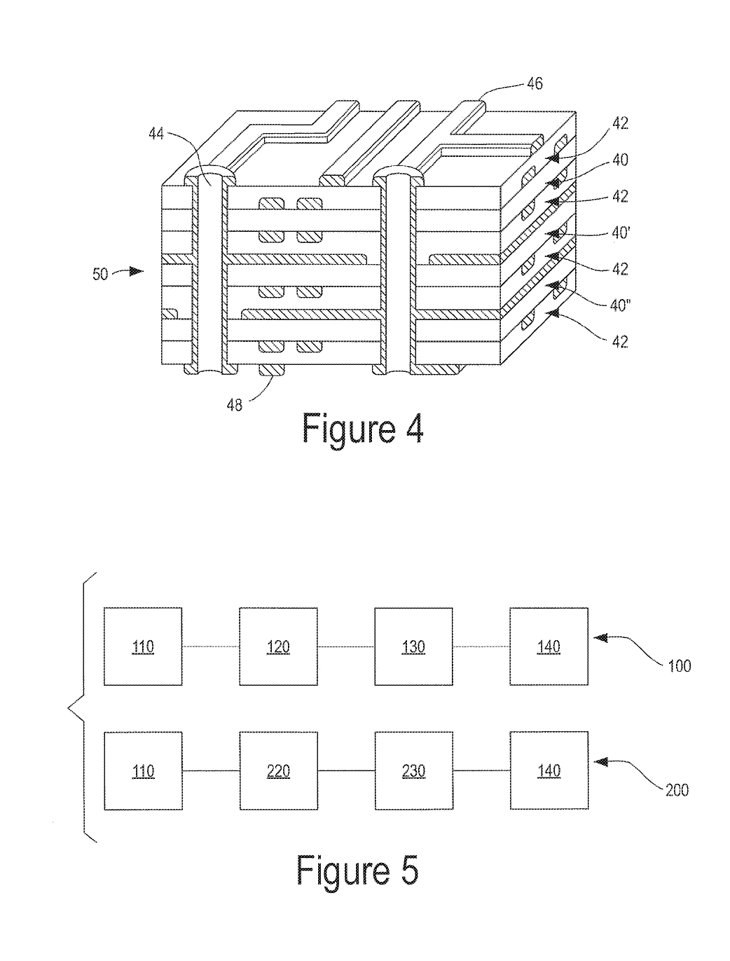

FIG. 4 is a cutaway view of a printed circuit board (50) that includes one or more innerlayer sheets (40, 40′, 40″) of this invention. A typical printed circuit board includes at least one but more typically a plurality of inner layer sheets (40) optionally separated by prepregs (42) and including optional vias (44) linking circuits formed on different innerlayer sheets. The printed circuit board (50) may optionally include a top circuit (46) and a bottom circuit (48).

FIG. 5 is a schematic of a process for manufacturing printed circuit boards at two different manufacturing facilities—a first manufacturing facility (100) and a second manufacturing facility (200). According to the method in step (110) the same planar sheet is provided as a PCB part at both manufacturing facilities. The provided planar sheet (110) including a planar dielectric material layer having a first planar surface and a second planar surface, and a first copper foil sheet having a first planar surface and a second planar surface wherein the first copper foil planar surface is associated with the first dielectric material layer planar surface and wherein the first copper foil sheet first surface and second surface each include a bond enhancment layer;

Next, in step (120) and (220) essentiall, the same transmission line structure is formed in the first planar copper sheet at each of the first and second manufacting facility by removing unnecessary portions of the first planar copper sheet while leaving the circuit copper in place to form an first manufactured innerlayer sheet including the transmission line structure. During this step a bond enhancment layer is not applied to the transmission line structure. The resulting transmission line structure includes a first transmission line having a circuit loss.

The method (120) used to form the transmission line structure at the first manufacting facility may be the same as or different that the method (220) used to form the transmission line structure at the second manufacturing facility. For example a positive photoresist may be used in one step and a negative photoresist in another. This is but one example of how the methods for forming a transmission line structre may vary between the first and second manufacturing facility and other process variation will be within the knowledge of one skilled in the art.

Next, in step (130) and (230) the innerlayer sheet including the transmission line structure is incorporated into a printed circuit board. The printed circuit board (shown in FIG. 4) may have a single innerlayer sheet (40) or a plurality of innerlayer sheets (40′, 40″) separated by one or more prepreg layers (42). The layers are stacked on on top of the other to form a layup which is then exposed to heat and pressure to bond the sheets together. Any further processing, such as via formation, outer suraface plating and circuit formation and so forth can be completed to form the final printed circuit board at each of the first and second manufacturing facilities. Examples of PCB processing steps that might be performed include lamination, via drilling, direct metallization, outer layer imaging, plating, strip/etch outer layer, solder mask application, final finishing, routing to form individual PCBs and electrical testing and inspection. In addtion, in one apect, a plurality of essentially identical PCB's are manufactured at the first manufacturing facility and a pluralty of essentially identical PCB's are manufactured at the second manfactuing facility. Moreover the PCB's manufactured at the first manufacturing facility are essentially identical to the PCB's manufactured at the second manufacturing facility. The term “essentially identical” in this context means that the manufactured PCB are intended for the same use, e.g., as a PCB motherboard or as the primary circuit board for a particular cell phone model.

As with the transmission line structure formation, the steps undertaken to form the printed circuit board at the first and second manufactring facility my be the same or they may be different. However in one aspect, a plurality of PCBs produced at the first manufactuing facility and a plurality of PCB's produced at the second manufactuing facility each have an innerlayer having the same curcuit structure and at least one essentially identical transmission line. In step (140) the total loss of each essentially identical transmission line of the plurlality of PCB's are tested. Because the original provided innerlayers (110) included a copper layer having first and second bond enhancment layers made by the same methods, the circuit loss should vary across a plurality of PCB's by no more than about 10%.

In general, the term “loss” as used herein refers to “total loss”—all of the signal power that is not delivered to the receiver of a communication system due to unwanted effects in the channel media. There are many possible causes of signal power loss in a generic channel including imperfections of printed circuit board materials and fabrication processes that influence electric signal integrity. At the PCB transmission line level, there are various sources of loss including propagation loss. In one aspect, “loss” is measured using one of four test methods described in IPC TM-650 2.5.5.12. The four loss test methods include Root Impulse Energy (RIE), Equivalent Bandwidth (EBW), Sparameters, & Short Pulse Propagation (SPP). In another aspect the loss can refer to insertion loss of the transmission line alone or in combination with dielectric loss. Total insertion loss (αT) is measured by adding conductor (αC), dielectric (αD), radiation (αR) and leakage losses (αL).

Having described products and methods of using the products in detail, it will be apparent that modifications and variations are possible without departing from the scope of the disclosure defined in the appended claims. More specifically, although some aspects of the present disclosure are identified herein as particularly advantageous, it is contemplated that the present invention is not necessarily limited to these particular aspects of the disclosure.

1. A method for manufacturing printed circuit boards comprising the steps of:
i. providing a planar sheet including a planar dielectric material layer having a first planar surface and a second planar surface, and first copper foil sheet having a first planar surface and a second planar surface wherein the first copper foil planer surface is associated with the first dielectric material layer planar surface and wherein the first copper foil sheet first surface and second surface each include a bond enhancment layer; and
ii. forming a circuit pattern in the first planar copper sheet by removing unnecessary portions of the first planar copper sheet while leaving the circuit pattern copper in place to form an innerlayer sheet including a circuit pattern wherein a bond enhancment layer is not applied to the circuit pattern.

2. The method of claim 1 wherein a dielectric material layer is laminted to the innerlayer sheet such that the dielectric material layer adhered to to the second planar surface of the circuit pattern.

3. The method of claim 1 wherein bond enhancement methods are used to apply bond enhancment layers to the planar copper foil sheet first and second surfaces.

4. The method of claim 3 wherein a first bond enhancment method is used to apply the bond enhancment layer to the planar copper foil sheet first surface and a second bond enhancment method is used to apply the bond enhancement layer to the planar copper foil sheet second surface and wherein the first bond enhancement method and second bond enhancment method are different bond enhancement methods.

5. The method of claim 1 wherein the bond enhancement layers have a Rz roughness of from about 0.25 to about 5.0 microns.

6. The method of claim 1 wherein the surface roughness of the first planar copper foil sheet first planar surface is less than about 1.5 microns.

7. The method of claim 1 wherein the surface roughness of the first copper foil sheet second planar surface is less than about 2.5 microns.

8. The method of claim 1 wherein the circuit pattern includes a bottom wall corresponding to the first copper sheet first planar surface, a top wall corresponding the to first copper foil sheet second planar surface and side walls, wherein the side walls do not include a bond enhancment layer.

9. The method of claim 1 wherein the innerlayer sheet includes a circuit pattern having a plurality of transmission lines.

10. The method of claim 1 wherein the planar sheet includes second copper foil sheet having a first planar surface and a second planar surface wherein the second copper foil first planer surface is assicated with the dielectric material layer second planar surface and wherein the second planar copper foil sheet first surface and second surface each include a bond enhancment layer.

11. The method of claim 10 wherein a circuit pattern is formed in the second copper sheet wherein a bond enhancment layer is not applied to the circuit pattern.

12. The method of claim 1 wherein a layup is formed by stacking at least one innerlayer sheet on a prepreg.

13. The method of claim 1 wherein the roughness of the first and second planer copper surfaces of the first copper foil sheet are essentially the same.

14. The method of claim 1 wherein the roughness of the first and second planar copper surfaces of the first copper foil sheet ranges from about 0.1 to about 6.0 microns.

15. The method of claim 1 wherein the copper foils is selected from a 1 ounce copper foil, a ½ ounce copper foil and a ¼ ounce copper foil.

16. The method of claim 1 wherein the first copper foil sheet is a low profile copper foil sheet having a thicknesses of from 10 to 400 microns and more preferably very low profile copper sheets having thicknesses of from about 5 microns to about 200 microns and more narrowly, from about 5 to about 35 microns.

17. The method of claim 1 wherein at least one first copper sheet bond enhancement layer includes a coating.

18. The method of claim 9 wherein the circuits pattern includes a plurality of transmission lines having widths of from about 25 to about 250 microns.

19. The method of claim 1 wherein the bond enhancement layers are imparted on the first and second planar copper surfaces of the first copper foil sheet simultaneously.

20. The method of claim 1 wherein the planar sheet is selected from resin coated copper, a copper clad prepreg or a c-staged laminate.

21. A method of manufacturing a plurality of printed circuit boards comprising the steps of:
a. manufacturing a plurality printed circuit boards at a first manufacturing location by the further steps of:
providing a planar sheet including a dielectric material layer having a first planar surface and a second planar surface, and a first copper foil sheet having a first planar surface and a second planar surface wherein the first copper foil first planar surface is associated with the dielectric material layer first planar surface and wherein the first copper foil sheet first planar surface and second planar surface each include a bond enhancment layer;
forming a circuit pattern in the first copper foil sheet by removing unnecessary portions of the first planar copper sheet while leaving the circuit patter copper in place to form an first manufactured innerlayer sheet including the circuit pattern wherein a bond enhancment layer is not applied to the circuit pattern and wherein the circuit pattern includes a transmission line having a total loss; and
incorporating the first manufactured innerlayer sheet into a first manufacuted printed circuit board; and
b. manufactuing a plurality of printed circuit boards at a second manufacturing location by the further steps of:
providing a planar sheet including a dielectric material layer having a first planar surface and a second planar surface, and a first copper foil sheet having a first planar surface and a second planar surface wherein the first copper foil sheet first planar surface is associated with the dielectric material layer first planar surface and wherein the first copper foil sheet first surface and second surface each include a bond enhancment layer; and
forming a circuit pattern in the first planar copper sheet by removing unnecessary portions of the first planar copper sheet while leaving the circuit pattern copper in place to form an second manufactured innerlayer sheet including a circuit pattern wherein a bond enhancment layer is not applied to the circuit pattern and wherein the circuit pattern includes a transmission line having a total loss; and
incorporating the second manufactured innerlayer sheet into a second manufacuted printed circuit board wherein the transmission line of the first manufactured innnerlayer is essentially identical to the transmission line of the second manufactured innerlayer;
c. repeating steps (a) and (b) a plurality of times to form a plurality of first manufactured innerlayers and second manufactured innerlayers wherein wherein the measured total loss of the transmission line of at least 90 percent of the plurality of first manufactured innerlayer and measured total loss of the transmission line of at least 90 percent of the plurality of second manufactured inner layers differ from one another by no more than 10%.

22-56. (canceled)
